(19) United States
(12) Patent Application Publication
(10) Pub. No.: US 2026/0068373 A1
(43) Pub. Date: Mar. 5, 2026

(54) DIE ATTACH STRUCTURES FOR LIGHT-EMITTING DIODE CHIPS ON LEAD FRAMES

(71) Applicant: CreeLED, Inc., Durham, NC (US)

(72) Inventors: Seth Joseph Balkey, Pittsboro, NC (US); Peter Scott Andrews, Durham, NC (US)

(21) Appl. No.: 18/825,032

(22) Filed: Sep. 5, 2024

(51) Int. Cl. H01L 33/62; H01L 23/00

(52) U.S. Cl. CPC H10H 20/857

(57) ABSTRACT

Light-emitting diode (LED) devices and more particularly die attach structures for LED chips on lead frames in LED packages are disclosed. Exemplary lead frame structures are provided with selectively plated metal layers at die attach regions for LED chips. The metal of the selectively plated metal layers is positioned to form alloys and/or intermetallic compounds with bonding materials employed for die attach of LED chips. The resulting alloys and/or intermetallic compounds form non-reflowable metal structures at and above temperatures utilized for subsequent attachment of LED packages in LED devices, thereby providing increased mechanical and electrical integrity of die attach for LED chips.

### FIELD OF THE DISCLOSURE

The present disclosure relates to light-emitting diode (LED) devices, and more particularly to die attach structures for LED chips on lead frames in LED packages.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs continue to enable a variety of new LED display and general illumination applications.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to die attach structures for LED chips on lead frames in LED packages. Exemplary lead frame structures are provided with selectively plated metal layers at die attach regions for LED chips. The metal of the selectively plated metal layers is positioned to form alloys and/or intermetallic compounds with bonding materials employed for die attach of LED chips. The resulting alloys and/or intermetallic compounds form non-reflowable metal structures at and above temperatures utilized for subsequent attachment of LED packages in LED devices, thereby providing increased mechanical and electrical integrity of die attach for LED chips.

In one aspect, an LED package comprises: a housing forming a recess with a recess floor; a lead frame within the housing; a metal pad in the recess, the metal pad formed on only a portion of the lead frame; an LED chip on the metal pad; and a bonding structure between the LED chip and the metal pad, the bonding structure comprising a non-reflowable metal structure configured to remain in a solidus state at temperatures up to at least 280 degrees Celsius (° C.). In certain embodiments, the non-reflowable metal structure is configured to remain in a solidus state at temperatures up to at least 380° C. In certain embodiments, the non-reflowable metal structure is configured to remain in a solidus state at temperatures in a range from 245° C. to 380° C. In certain embodiments, the metal pad comprises nickel. In certain embodiments, the bonding structure comprises an alloy layer comprising nickel and a metal of a solder material. In certain embodiments, wherein the metal of the solder material comprises tin and the alloy layer comprises nickel-tin. In certain embodiments, the metal of the solder material comprises one or more of gold, antimony-tin, tin-silver-copper, and tin-lead. In certain embodiments, wherein the alloy layer is a first alloy layer at a first interface with the metal pad, and the bonding structure further comprises a second alloy layer at a second interface with a contact pad of the LED chip, and the second alloy layer comprises the metal of the solder material. In certain embodiments, the alloy layer is continuous from a first interface with the metal pad to a second interface with a contact pad of the LED chip. In certain embodiments, a thickness of the metal pad above the recess floor is in a range from 5 (microns) μm to 25 μm. In certain embodiments, a portion of the lead frame extends above the recess floor; and the metal pad covers a top surface of the lead frame and one or more perimeter sidewalls of the lead frame above the recess floor. In certain embodiments, a top surface of the lead frame is below the recess floor; and the metal pad covers the top surface of the lead frame. In certain embodiments, wherein the metal pad is discontinuous between a contact pad of the LED chip and a lead of the lead frame. In certain embodiments, the metal pad forms an array pattern on the lead of the lead frame. The LED package may further comprise a light-altering material on the recess floor and covering perimeter sidewalls of the LED chip. The LED package may further comprise at least one metal pillar, wherein peripheral edges of the at least one metal pillar are laterally surround by the metal pad.

In another aspect, a lead frame structure for an LED package comprises: a housing forming a recess with a recess floor; a lead frame comprising a first lead within the housing, a portion of the first lead being positioned along the recess floor; and a first metal pad on the portion of the first lead at the recess floor, the first metal pad comprising nickel. In certain embodiments, a thickness of the first metal pad above the first lead is in a range from 5 μm to 25 μm. In certain embodiments: a portion of the first lead extends above the recess floor; and the first metal pad covers a top surface of the first lead and one or more perimeter sidewalls of the first lead above the recess floor. In certain embodiments: a top surface of the first lead is below the recess floor; and the first metal pad covers the top surface of the first lead. In certain embodiments, the first metal pad is discontinuous on the first lead. In certain embodiments, the lead frame comprises a second lead within the housing and a portion of the second lead is positioned along the recess floor, wherein the first lead and the second lead collectively form a die attach area. The lead frame structure may further comprise a second metal pad on the portion of the second lead at the recess floor, the second metal pad comprising nickel.

In another aspect, a lighting device comprises: a board; and an LED package mounted on the board, the LED package comprising: a housing forming a recess with a recess floor; a lead frame within the housing; a metal pad in the recess, the metal pad formed on only a portion of the lead frame; an LED chip on the metal pad; and a bonding structure between the LED chip and the metal pad, the bonding structure comprising a non-reflowable metal structure configured to remain in a solidus state at temperatures up to at least 280 degrees ° C. In certain embodiments, the non-reflowable metal structure is configured to remain in a solidus state at temperatures in a range from 245° C. to 380° C. In certain embodiments, the metal pad comprises nickel.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top view of an exemplary light-emitting diode (LED) package according to principles of the present disclosure.

FIG. 1B is a cross-sectional view of the LED package of FIG. 1A taken along the sectional line 1B-1B of FIG. 1A.

FIG. 2A is a cross-sectional view of the LED package of FIG. 1B at a fabrication step before mounting an LED chip to the lead frame structure.

FIG. 2B is an expanded cross-sectional view of a portion of the LED package of FIG. 2A illustrating details of the lead and metal pad relative to the LED chip contact of the LED chip.

FIG. 2C is a cross-sectional view of the LED package of FIG. 2A at a subsequent fabrication step after mounting the LED chip to the lead frame structure.

FIG. 2D is an expanded cross-sectional view of a portion of the LED package of FIG. 2C illustrating details of a first configuration for the LED chip bonding structure.

FIG. 2E is an alternative expanded cross-sectional view of a portion of the LED package of FIG. 2C illustrating details of another configuration of the LED chip bonding structure.

FIG. 2F is an expanded cross-sectional view of a portion of the LED package of FIG. 2C for embodiments that further comprise thermally and/or electrically conductive structures embedded along bonding interfaces.

FIG. 2G is an expanded cross-sectional view of a portion of the LED package of FIG. 2C for embodiments that comprise alternative thermally and/or electrically conductive structures embedded along bonding interfaces.

FIG. 3A is a cross-sectional view of an LED package similar to the LED package of FIG. 2C for embodiments where the metal pads wrap around perimeter edges of the leads.

FIG. 3B is a magnified cross-sectional view of a portion of the LED package of FIG. 3A illustrating the metal pad and corresponding LED chip bonding structure.

FIG. 4A is a cross-sectional view of an LED package similar to the LED package of FIG. 3A for embodiments where the leads are recessed below the recess floor.

FIG. 4B is a magnified cross-sectional view of a portion of the LED package of FIG. 4A illustrating the metal pad and corresponding LED chip bonding structure.

FIG. 5A is a top view of an LED package that is similar to the LED package of FIGS. 1A to 2E for embodiments where one or more of the metal pads have discontinuous portions on respective leads.

FIG. 5B is a cross-sectional view of the LED package of FIG. 5A taken along the sectional line 5B-5B of FIG. 5A and illustrating formation of a gap between portions of respective leads.

FIG. 6 is a cross-sectional view of a portion of an LED package that is similar to the LED package of FIGS. 5A to 5B for embodiments where the gap of FIG. 5B is filled by the housing.

FIG. 7 is a top view of an LED package that is similar to the LED package of FIGS. 5A to 5B for embodiments where the metal pads form respective array patterns.

FIG. 8 is a cross-sectional view of an LED package similar to the LED package of FIG. 3A for embodiments that include multiple encapsulation materials in the recess.

FIG. 9 is a cross-sectional view of an LED package similar to the LED package of FIG. 8 with an alternative shape for a lens.

FIG. 10 is a schematic diagram of a portion of an LED device, such as a display screen including a large number of LED packages according to principles of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to die attach structures for LED chips on lead frames in LED packages. Exemplary lead frame structures are provided with selectively plated metal layers at die attach regions for LED chips. The metal of the selectively plated metal layers is positioned to form alloys and/or intermetallic compounds with bonding materials employed for die attach of LED chips. The resulting alloys and/or intermetallic compounds form non-reflowable metal structures at and above temperatures utilized for subsequent attachment of LED packages in LED devices, thereby providing increased mechanical and electrical integrity of die attach for LED chips.

Before delving into specific details of various aspects of the present disclosure, an overview of elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements.

The active LED structure can be fabricated from different material systems, with some material systems being Group III nitride-based material systems. Group III nitrides refer to semiconductor compounds formed between nitrogen (N) and elements in Group III of the periodic table, usually aluminum (Al), gallium (Ga), and/or indium (In) in the form of binary, ternary, and/or quaternary compounds. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure can emit different wavelengths of light depending on the composition of the active layer. In certain embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B light is typically defined as a peak wavelength range from 280 nm to 315 nm, and UV-C light is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

Aspects of the present disclosure are applicable to multiple-chip LED packages where multiple LED chips are arranged within a common recess and sometimes beneath a common lens of an LED package. For example, LED packages may include a red-emitting LED chip, a green-emitting LED chip, and a blue-emitting LED chip such that the LED package may be positioned as a pixel in an LED display. In other embodiments, aspects of the present disclosure may be applicable to other LED packages, such as those that include one or more LED chips with a recipient lumiphoric material that converts at least a portion of light generated from the one or more LED chips to a different wavelength.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphoric material receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective).

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a support structure of an LED package such that the anode and cathode connections are on a face of the LED chip that is opposite the support structure. In this configuration, wire bonds may be used to provide electrical connections with the anode and cathode connections. In other embodiments, a lateral geometry LED chip may be flip-chip mounted on a surface of a support structure of an LED package such that the anode and cathode connections are on a face of the active LED structure that is adjacent to the support structure. In this configuration, electrical traces or portions of a lead frame may be provided with the support structure for providing electrical connections to the anode and cathode connections of the LED chip. In a flip-chip configuration, the active LED structure is configured between the substrate of the LED chip and the support structure for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a lead frame structure or a submount. Lead frame structures are typically at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. In certain embodiments, one or more lumiphoric materials, such as phosphor particles, may be integrated or otherwise embedded within the encapsulant material.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Light-altering materials may be arranged within LED packages to reflect or otherwise redirect light from the one or more LED chips in a desired emission direction or pattern. Encapsulant materials may be formed to cover LED chips and portions of the submount and in certain embodiments, encapsulant materials may form lenses that direct light in desired emission directions and/or patterns.

Light-altering materials may be arranged within LED packages, such as within housings and/or within portions of recesses thereof, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

Within LED packages with lead frame structures, LED chips may be die-attached to the lead frame by way of a solder attach material. In certain embodiments, the bonding of the LED chip electrically couples anode and/or cathode contacts of the LED chip to corresponding leads of the lead frame. The leads are formed to extend away from the die attach areas of the LED chip to provide electrically conductive paths to package anode and cathode connections arranged to receive external electrical connections for powering the LED package. Flatness control between opposing leads is challenging in lead frame structures. In order to accommodate potential unevenness, bonding materials for the LED chip are typically thicker than those for submount-based LED packages.

When the LED package is later assembled in an end use product, such as an LED display or a lighting fixture, the package anode and cathode connections are bonded to another surface, such as a printed circuit board or the like. During package bonding, the LED package may be subject to high temperatures. For example, surface mount LED packages are typically subjected to temperatures of about 245° C. during package bonding. At these temperatures, bonding materials used to previously attach the LED chip to the lead frame structure exhibit re-liquidation or reflow. In the example of solder attach between the LED chip and lead frame, the solder material may reflow and wick and/or spread along the lead frame structure. In this regard, the solder material may travel away from LED chip bonding areas to other portions of the lead frame structure accessible within the housing recess. Associated problems include forming rough surfaces of reflow material within the recess that may create unwanted light scattering surfaces that impact color mixing and/or far field patterns of light emissions. Other problems associated with solder reflow include too much solder material traveling away from intended bonding locations, thereby decreasing mechanical and/or electrical integrity of bonding between the LED chip and lead frame structure. In such instances, decreased performance and/or product failure may be related to poor electrical connections for the LED chip or reduced thermal conductivity between the LED chip and the lead frame structure.

According to aspects of the present disclosure, lead frame structures are provided with selectively plated metal layers configured to form alloys and/or intermetallic compounds with bonding materials after initial die attach. The resulting bond structure may then avoid reflow and remain in a solidus state at package bonding temperatures. By way of example, a die attach area of a lead frame may be defined as a portion of the lead frame where the LED chip is bonded. For flip-chip configurations, the die attach area includes portions of two leads separated by a gap where anode and cathode contacts of the LED chip are respectively bonded to corresponding leads. The selectively plated metal layer may be provided on the portions of the two leads defining the die attach area, thereby building up a thickness of the lead frame at the die attach area relative to other portions of the lead frame. In this manner, the selectively plated metal layer may form metal pads at the die attach area.

Materials of the metal pad are chosen based on their ability to form alloys and/or intermetallic compounds with the die attach material, for example solder material. In one example, the solder material comprises tin (Sn) and the metal pad comprises nickel (Ni). Before initial die attach, both the Sn and the Ni may readily exhibit reflow at lower relative temperatures. After die attach, alloys and/or intermetallic compounds of Ni—Sn are formed that exhibit much higher reflow temperatures, thereby providing stable LED chip bonding structures at package bonding temperature. For example, the resulting LED chip bonding structures may form a non-reflowable metal structure that remains in a solidus state at temperatures above 232° C. where conventional bonding structures reflow. In certain embodiments, the LED chip bonding structures remain in a solidus state at temperatures from where conventional structure reflow (e.g., about 232° C.) or from package bonding temperatures (e.g., about 245° C.) up to at least 250° C., or at least 260° C., or at least 280° C., or at least 380° C. In practice, lead frame structures are typically subjected to temperatures of about 245° C. during package bonding to avoid subjecting other portions of the LED package to higher temperatures. For example, plastic materials of housings in lead frame structures may start to warp at about 280° C. By forming LED chip bonding structures that remain solid up to at least 380° C., reflow temperatures are well avoided to provide stable bonding interfaces for LED chips. In addition to Sn, other materials for forming alloys and/or intermetallic compounds with selectively plated Ni of the metal pad include gold (Au), antimony-tin (Sb—Sn), tin-silver-copper (Sn—Ag—Cu), and tin-lead (Sn—Pb), among others.

A thickness of the selectively plated Ni for the metal pad may be in a range from 0.1 micron (μm) to 50 μm, or in a range from 5 μm to 25 μm, depending on the embodiment. Considerations for thickness include the relative LED chip size where thicker metal pads are implemented for larger chip sizes. Additionally, thicker metal pads may also provide improved thermal spreading for the LED chip.

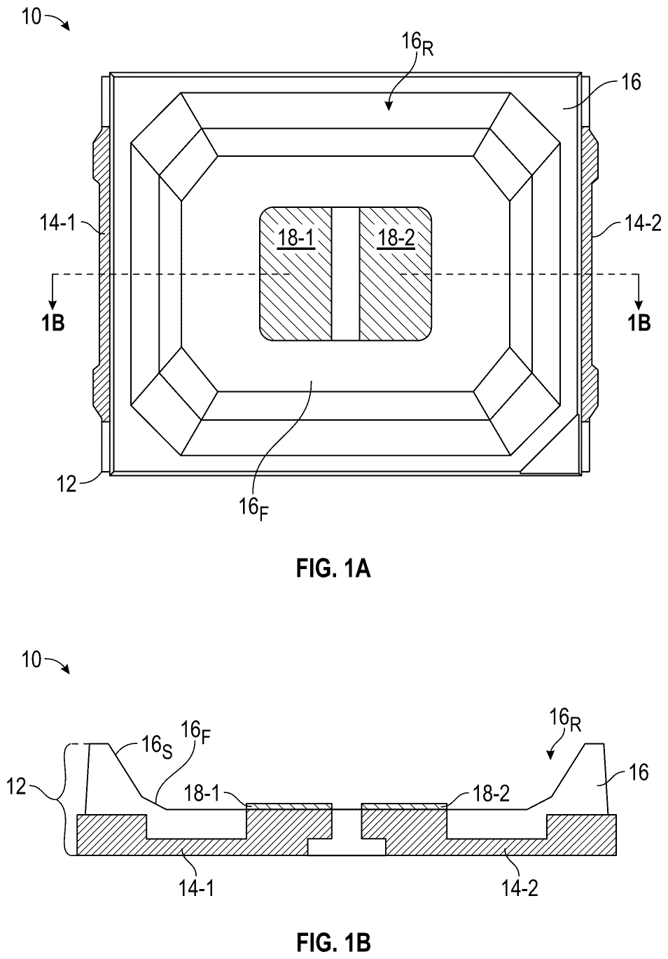

FIG. 1A is a top view of an exemplary LED package 10 according to principles of the present disclosure. FIG. 1B is a cross-sectional view of the LED package 10 of FIG. 1A taken along the sectional line 1B-1B of FIG. 1A. The LED package 10 includes a lead frame structure 12 collectively formed by a plurality of leads 14-1, 14-2, and a body or housing 16 that encases a portion of the lead frame structure. The housing 16 forms a recess 16_{R} with a perimeter thereof defined by one or more recess sidewalls 16_{S} and a recess floor 16_{F} at a base of the recess 16_{R}. Within the recess 16_{R}, metal pads 18-1, 18-2 collectively form a die attach area for an LED chip that will be mounted thereon. The metal pads 18-1, 18-2 are selectively plated on respective portions of the leads 14-1, 14-2, thereby increasing a height of a mounting surface for the LED chip above the recess floor 16_{F}. In this regard, the metal pads 18-1, 18-2 may form pedestals into the recess 16_{R}. The metal pads 18-1 and 18-2 may be selectively formed by various techniques, such as selective plating or hot air solder leveling.

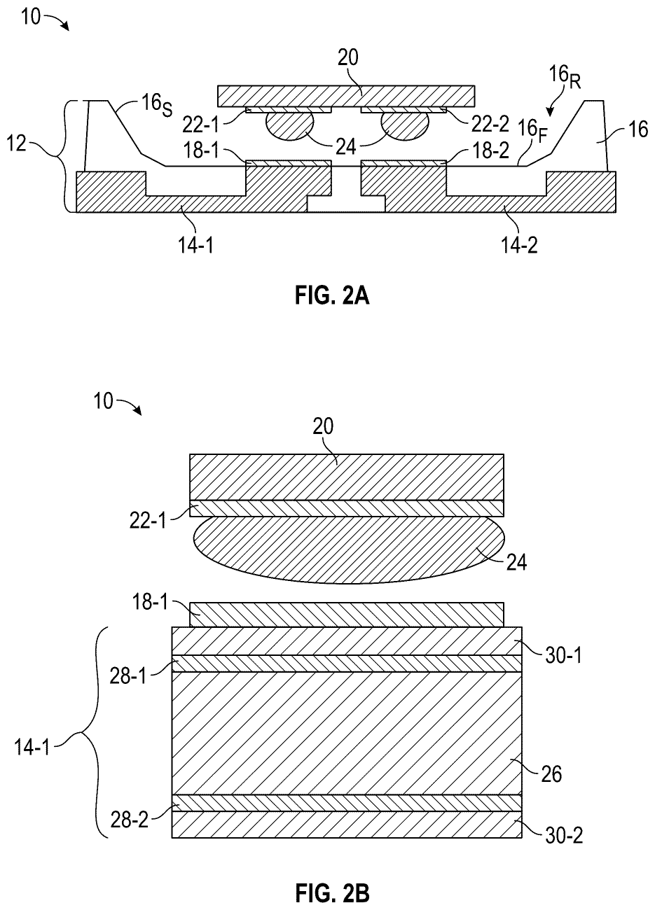

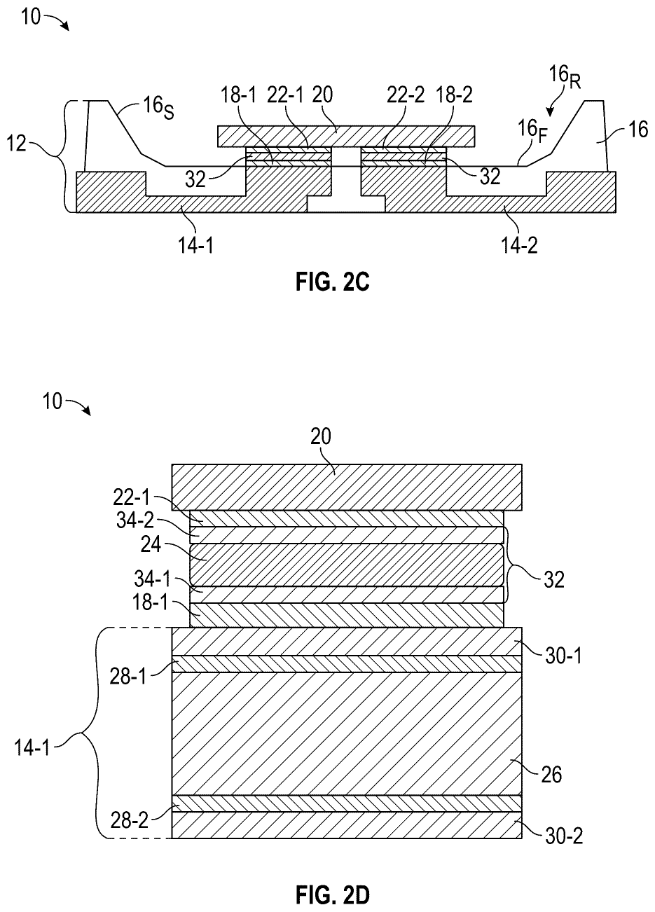

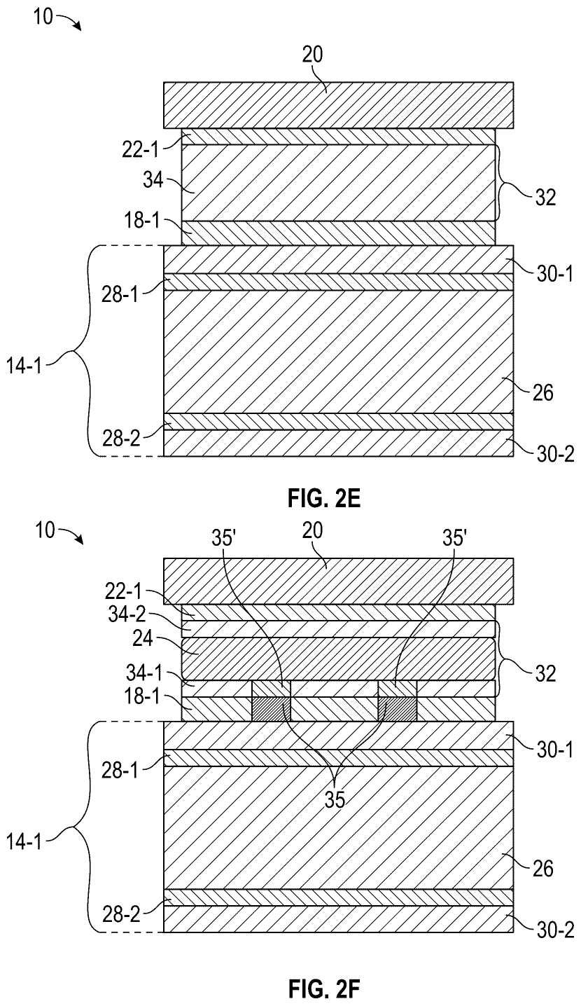

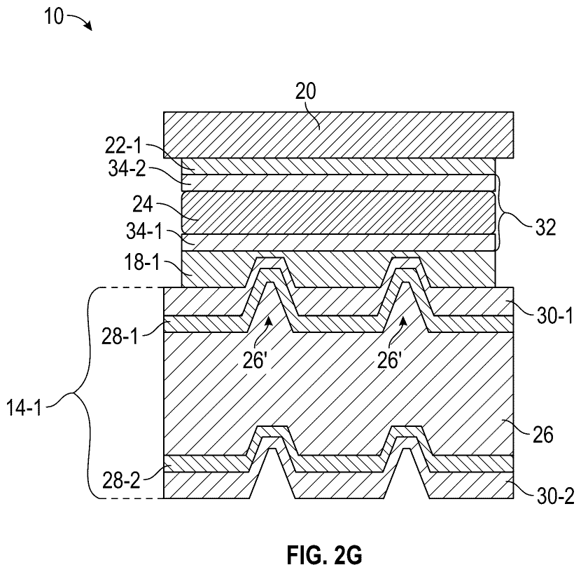

FIG. 2A is a cross-sectional view of the LED package 10 of FIG. 1B at a fabrication step before mounting an LED chip 20 to the lead frame structure 12. In FIG. 2A, the LED chip 20 is arranged for flip-chip mounting to the lead frame structure 12. Accordingly, LED chip contacts 22-1, 22-2 of the LED chip 20 form anode and cathode contact pads positioned to be mounted and electrically connected to corresponding leads 14-1, 14-2. A solder material 24 is positioned between the LED chip contacts 22-1, 22-2 and corresponding leads 14-1, 14-2.

FIG. 2B is an expanded cross-sectional view of a portion of the LED package 10 of FIG. 2A illustrating details of the lead 14-1 and metal pad 18-1 relative to the LED chip contact 22-1 of the LED chip 20. While FIG. 2B is described in the context of the lead 14-1, the metal pad 18-1, and the LED chip contact 22-1, the principles described are equally applicable to the lead 14-2, the metal pad 18-2, and the LED chip contact 22-2 of FIG. 2A. As illustrated in FIG. 2B, the lead 14-1 may embody a multiple layer structure having a core 26 with first coating layers 28-1, 28-2 on either side of the core 26, followed by second coating layers 30-1, 30-2 on either side of the first coating layers 28-1, 28-2. By way of example, the core 26 may comprise copper (Cu), the first coating layers 28-1, 28-2 may comprise Ni, and the second coating layers 30-1, 30-2 may comprise silver (Ag) to form outer surfaces with improved electrical conductivity, reflectivity, and/or corrosion resistance. As described above, Ni is an exemplary metal for the metal pad 18-1 for forming alloys and/or intermetallic compounds with the solder material 24 after die attach. In certain embodiments, the LED chip contact 22-1 may also comprise Ni at a surface of the LED chip contact 22-1 that is closest to the solder material 24. In this regard, alloys and/or intermetallic compounds that remain solidus at higher temperatures may be formed on both sides of the solder material 24.

FIG. 2C is a cross-sectional view of the LED package 10 of FIG. 2A at a subsequent fabrication step after mounting the LED chip 20 to the lead frame structure 12. As illustrated, the LED chip 20 is mounted to a surface of the metal pads 18-1, 18-2 that is raised relative to the recess floor 16_{F}. An LED chip bonding structure 32 is formed between respective pairs of the metal pads 18-1, 18-2 and the LED chip contacts 22-1, 22-2 after die attach. FIG. 2D is an expanded cross-sectional view of a portion of the LED package 10 of FIG. 2C illustrating details of a first configuration for the LED chip bonding structure 32. FIG. 2E is an alternative expanded cross-sectional view of a portion of the LED package 10 of FIG. 2C illustrating details of another configuration of the LED chip bonding structure 32.

As best illustrated in FIG. 2D, during elevated temperatures associated with die attach, metal reflow of portions of the solder material 24 and the metal pad 18-1 form an alloy layer 34-1 at a first interface therebetween. In a similar fashion, portions of the solder material 24 and portions of the LED chip contact 22-1 form another alloy layer 34-2 at a second interface therebetween. The resulting alloy layers 34-1, 34-2 exhibit much higher melting temperatures than the solder material 24, thereby providing increased temperature stability during subsequent reflow for the LED package 10. In certain embodiments, the alloy layers 34-1, 34-2 may form intermetallic layers. In certain embodiments, the formation of the alloy layers 34-1, 34-2 may be controlled by adjusting die attach parameters, such as time above melting temperatures for the solder material 24. For example, the die attach process may be performed such that a portion of the solder material 24 remains between the alloy layers 34-1, 34-2 in the LED chip bonding structure 32 as illustrated in FIG. 2D. In further embodiments, the die attach process may be controlled such that little or no solder material 24 remains as illustrated in FIG. 2E. With longer time above the melting temperature of the solder material 24, the alloy layers 34-1, 34-2 of FIG. 2D may expand towards one another, and in some cases join to form a single alloy layer 34 that is continuous from an interface with the metal pad 18-1 to another interface with the LED chip contact 22-1. For such embodiments, the cross-sectional view of FIG. 2D may represent initial formation of the alloy layers 34-1, 34-2 before joining to form the LED chip bonding structure 32 with the single alloy layer 34.

In certain embodiments, the LED package 10 may further include one or more thermally and/or electrically conductive structures at or near the bonding interfaces between the LED chip 20 and the lead frame structure. The choice of metal for the metal pads 18-1, 18-2 and/or the LED chip contacts 22-1, 22-2 for forming the alloy and/or intermetallic compounds may sometimes reduce heat transfer and/or electrical conductivity at these bonding interfaces. According to aspects of the present disclosure, the bonding interfaces may include thermal and/or electrically conductive structures that improve heat transfer and/or lower forward voltages for the LED chip 20 as compensation for any decreases caused by the metal of the metal pads 18-1, 18-2 and/or the LED chip contacts 22-1, 22-2. Such thermally and/or electrically conductive structures may embody other metal structures, such as pillars, embedded within the bonding structures. In the example where the metal of the metal pads 18-1, 18-2 is Ni, the thermally and/or electrically conductive structures may comprise Cu, or another metal with improved thermal and/or electrical conductivity relative to Ni.

FIG. 2F is an expanded cross-sectional view of a portion of the LED package 10 of FIG. 2C for embodiments that further comprise thermally and/or electrically conductive structures embedded along bonding interfaces. As illustrated, at least one metal pillar 35 is positioned between the lead 14-1 and the solder material 24. In FIG. 2F, the at least one metal pillar 35 is integrated within the metal pad 18-1. In certain embodiments, the at least one metal pillar 35 forms an island such that peripheral edges of the metal pillar 35 are laterally surrounded by the metal pad 18-1. The presence of the metal pillar 35, for example a Cu pillar or other metal with increased conductivity relative to the metal pad 18-1, provides pathways for increased thermal and electrical conductivity. Moreover, during reflow, additional alloy 35′ segments (or intermetallic segments in certain embodiments) may form above each metal pillar 35. The at least one metal pillar 35 may be formed by selective plating.

FIG. 2G is an expanded cross-sectional view of a portion of the LED package 10 of FIG. 2C for embodiments that comprise alternative thermally and/or electrically conductive structures embedded along bonding interfaces. Instead of the metal pillar 35 structure of FIG. 2F, the lead frame structure may be subjected to a punching process that positions more material of the core 26 at or within the bonding interface with the LED chip 20. The punching process may form at least one integrated metal pillar or protrusion 26′ of the core 26 that may extend upward. The metal pad 18-1 may be formed after punching such that the metal pad 18-1 covers the protrusions 26′ and provides a generally planar bonding surface. In this manner, the metal pad 18-1 is thinner in portions directly above each protrusion 26′, thereby providing increased thermal and/or electrical conductivity. As with the embodiment of FIG. 2F, peripheral edges of the protrusion 26′, or metal pillar, are laterally surrounded by portions of the metal pad 18-1.

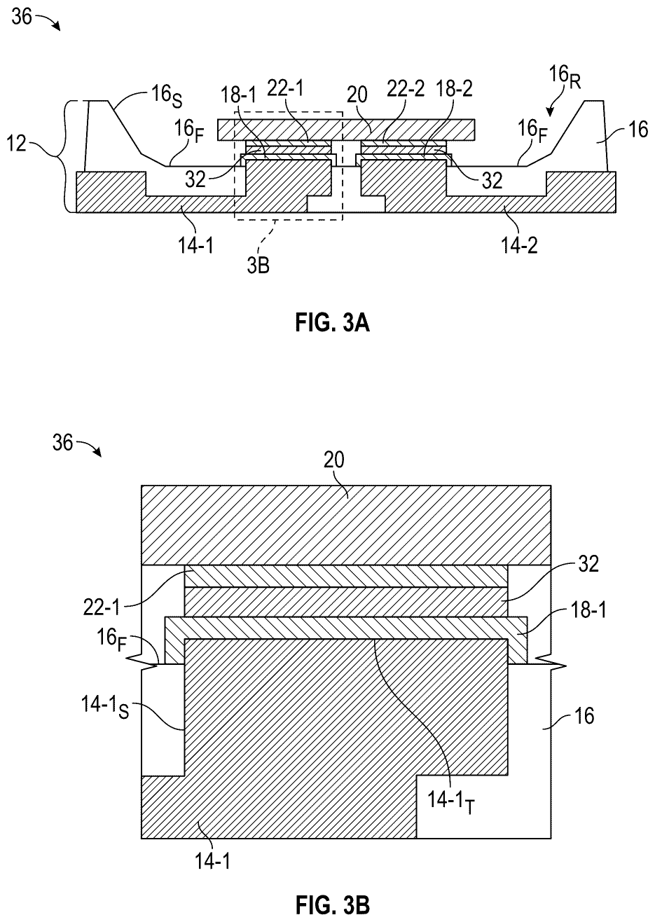

FIG. 3A is a cross-sectional view of an LED package 36 similar to the LED package 10 of FIG. 2C for embodiments where the metal pads 18-1, 18-2 wrap around perimeter edges of the leads 14-1, 14-2. FIG. 3B is a magnified cross-sectional view of a portion of the LED package 36 of FIG. 3A illustrating the metal pad 18-1 and corresponding LED chip bonding structure 32. In certain embodiments, portions of the leads 14-1, 14-2 may extend above the recess floor 16_{F} such that the leads 14-1, 14-2 form raised pedestals in the recess 16_{R}. As best illustrated in FIG. 3B, the metal pad 18-1 covers a top surface 14-1_{T} of the lead 14-1 and one or more perimeter sidewalls 14-1_{S} of the lead 14-1 above the recess floor 16_{F}. In certain embodiments, portions of the metal pad 18-1 may extend on portions of the recess floor 16_{F}. In further embodiments, the metal pad 18-1 may cover all surfaces of the lead 14-1 that are raised above the recess floor 16_{F} to ensure the LED chip bonding structure 32 is formed to the metal pad 18-1 and not directly to portions of the lead 14-1. While FIG. 3B is described in the context of the metal pad 18-1, the principles described are equally applicable to the metal pad 18-2 and the corresponding LED chip contact 22-2.

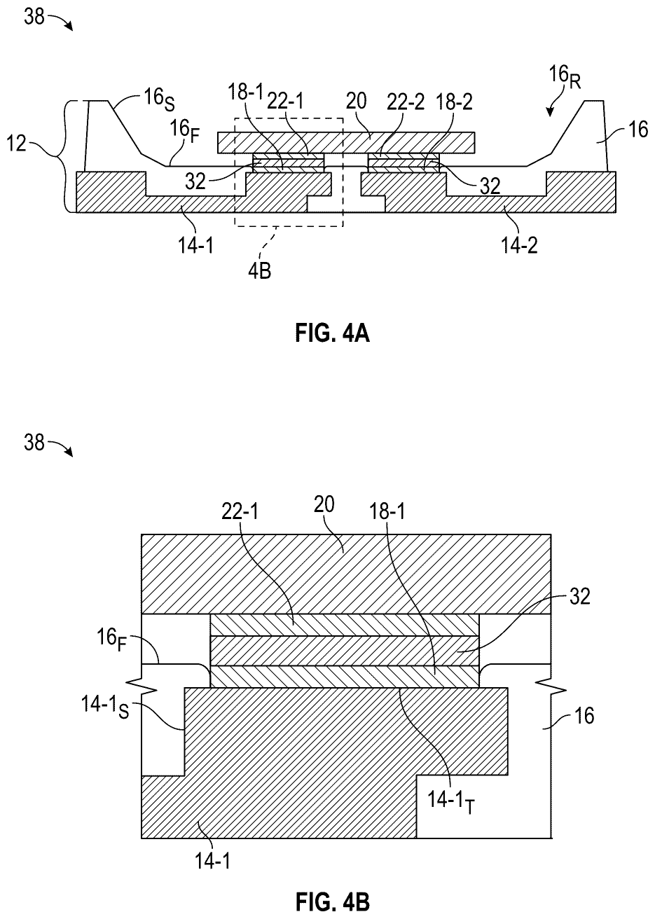

FIG. 4A is a cross-sectional view of an LED package 38 similar to the LED package 36 of FIG. 3A for embodiments where the leads 14-1, 14-2 are recessed below the recess floor 16_{F}. FIG. 4B is a magnified cross-sectional view of a portion of the LED package 38 of FIG. 4A illustrating the metal pad 18-1 and corresponding LED chip bonding structure 32. As illustrated, top surfaces (e.g., 14-1_{T} of FIG. 4B) of the leads 14-1, 14-2 are positioned below the recess floor 16_{F}, and the metal pads 18-1, 18-2 are formed with sufficient thickness to cover the exposed portions of the leads 14-1, 14-2 to ensure the LED chip bonding structure 32 is formed to the metal pad 18-1 and not directly to portions of the leads 14-1, 14-2. In certain embodiments, the thickness of the metal pads 18-1, 18-2 is arranged to at least reach the recess floor 16_{F}, and in further embodiments, the metal pads 18-1, 18-2 may extend above the recess floor 16_{F}. As best illustrated in FIG. 4B, the metal pad 18-1 covers a top surface 14-1_{T} of the lead 14-1, and one or more perimeter sidewalls 14-1_{S} of the lead 14-1 are covered by the housing 16. While FIG. 4B is described in the context of the metal pad 18-1, the principles described are equally applicable to the metal pad 18-2 and the corresponding LED chip contact 22-2.

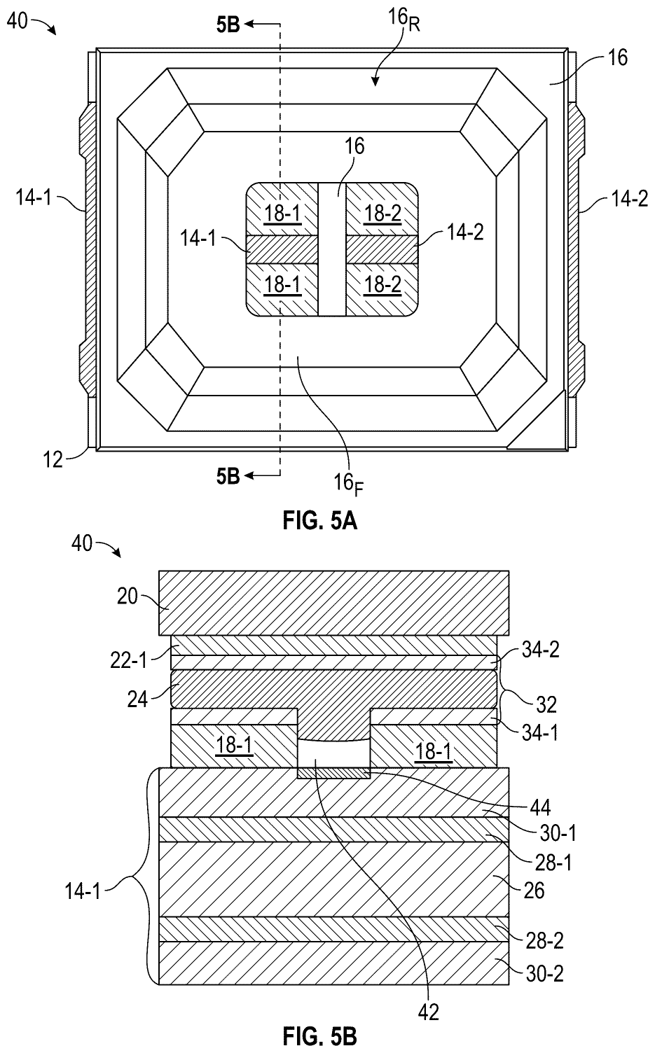

FIG. 5A is a top view of an LED package 40 that is similar to the LED package 10 of FIGS. 1A to 2E for embodiments where one or more of the metal pads 18-1, 18-2 have discontinuous portions on respective leads 14-1, 14-2. FIG. 5B is a cross-sectional view of the LED package 40 of FIG. 5A taken along the sectional line 5B-5B of FIG. 5A. Stress profiles in lead frame structures may be impacted with the addition of the selectively formed metal pads 18-1, 18-2. For example, the material of the metal pads 18-1, 18-2 may have a different coefficient of thermal expansion than the leads 14-1, 14-2. In certain implementations, the stress profile may cause warping or unevenness for the leads 14-1, 14-2, thereby comprising mounting integrity of the LED chip 20. This can be especially problematic for embodiments where the LED chip 20 is flip-chip mounted to the leads 14-1, 14-2. To provide stress relief and avoid warping, each of the metal pads 18-1, 18-2 may be selectively formed in a discontinuous nature. For example, the metal pad 18-1 may not entirely cover the portions of the lead 14-1 exposed at the recess floor 16_{F}, and the metal pad 18-2 may not entirely cover the portions of the lead 14-2 exposed at the recess floor 16_{F}. Accordingly, the LED package 40 may exhibit increased integrity of die attach for the LED chip 20 due to the presence of the metal pads 18-1, 18-2 while also reducing or avoiding associated warping.

As best illustrated in FIG. 5B, a gap 42 is formed between the discontinuous portions of the metal pad 18-1. The alloy layer 34-1 may form between the discontinuous portions of the metal pad 18-1 and the solder material 24. In such embodiments, a portion of the lead 14-1 is exposed in the gap 42, specifically a portion of the topmost second coating layer 30-1. During die attach, portions of the solder material 24 may spread into the gap 42 and an alloy 44 between metals of the solder material 24 and the second coating layer 30-1 may form into a surface of the second coating layer 30-1. Since the metal of the second coating layer 30-1 is different from the metal of the metal pad 18-1, the reflow temperature of the alloy 44 may be lower than the alloy layer 34-1. However, the alloy layer 34-1 remains in a solidus state during subsequent package mounting, thereby maintaining die attach integrity for the LED chip 20. In FIGS. 5A and 5B, the gap 42 between respective portions of each lead 14-1, 14-2 is in the form of a trench. The trench may partially or entirely separate respective portions of each lead 14-1, 14-2. In other embodiments, additional shapes and patterns are contemplated for the metal pads 18-1, 18-2, such as multiple stripe patterns, and multiple island or grid patterns, among others.

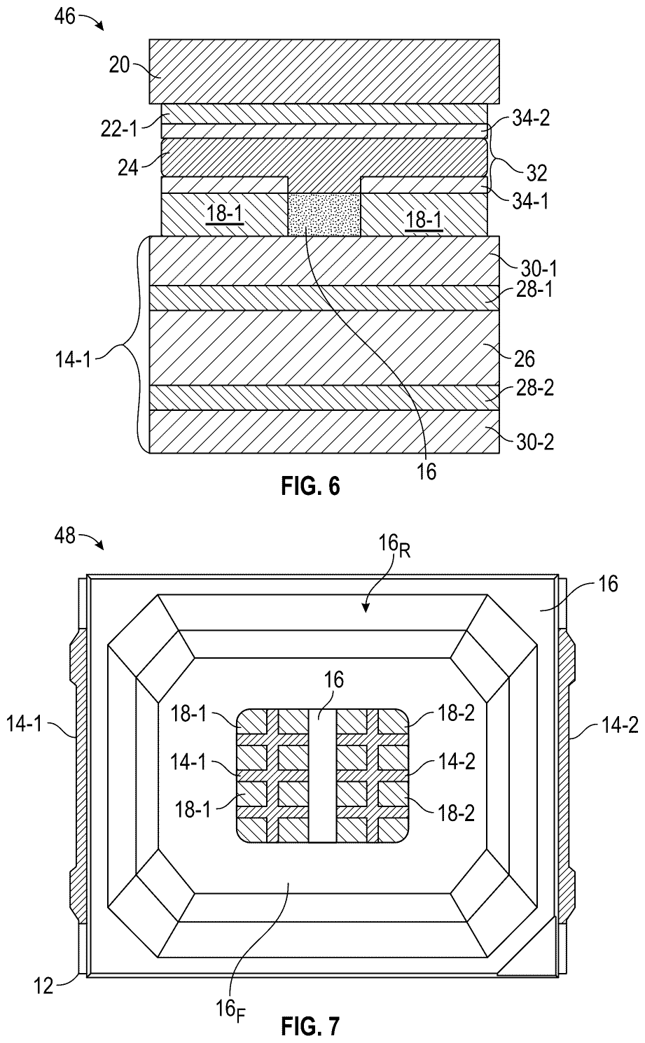

FIG. 6 is a cross-sectional view of a portion of an LED package 46 that is similar to the LED package 40 of FIGS. 5A to 5B for embodiments where the gap 42 of FIG. 5B is filled by the housing 16. As illustrated in FIG. 6, material of the housing 16 may fill the space between portions of the lead 14-1. During subsequent die attach, the alloy layer 34-1 may form on portions of the metal pad 18-1 at interfaces with the solder material 24. In certain embodiments, the solder material 24 may spread to cover portions of the housing 16 between portions of the metal pad 18-1.

FIG. 7 is a top view of an LED package 48 that is similar to the LED package 40 of FIGS. 5A to 5B for embodiments where the metal pads 18-1, 18-2 form respective array patterns. As illustrated, each metal pad 18-1, 18-2 may discontinuously cover a respective lead 14-1, 14-2 with a grid pattern or a pattern of discontinuous islands. As described above with respect to FIGS. 5A to 5B, the discontinuous pattern for the metal pads 18-1, 18-2 may provide enhanced die attach strength while also providing stress relief associated with the addition of the metal pads 18-1, 18-2.

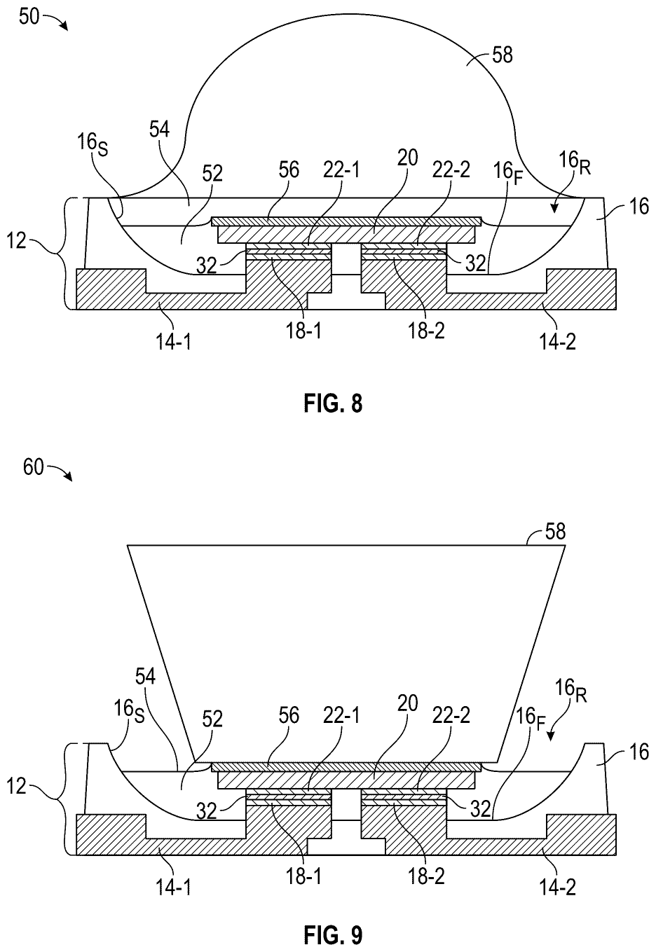

FIG. 8 is a cross-sectional view of an LED package 50 similar to the LED package 36 of FIG. 3A for embodiments that include multiple encapsulation materials in the recess 16_{R}. In certain embodiments, a light-altering material 52 may partially fill the recess 16_{R} along the recess floor 16_{F} and along perimeter edges of the LED chip 20. The light-altering material 52 may embody a light-reflecting and/or light-refracting material, such as at least one of fused silica, fumed silica, TiO₂, or metal particles suspended in a binder, such as silicone or epoxy. In such embodiments, the light-altering material 52 may comprise a generally white color to reflect and/or redirect light away from the recess floor 16_{F}. As illustrated, the leads 14-1, 14-2 form raised pedestals above the recess floor 16_{F} for elevating a mounting surface of the LED chip 20. In FIG. 8, the metal pads 18-1, 18-2 are illustrated on a top surface of the raised pedestals. However, the metal pads 18-1, 18-2 may also cover exposed perimeter edges of the raised pedestals in a same manner described above with respect to FIG. 3A. The light-altering material 52 may fill portions of the recess 16_{R} proximate the raised pedestals, the LED chip bonding structures 32, and the metal pads 18-1, 18-2 to reduce instances of light absorption in these areas.

As further illustrated in FIG. 8, an encapsulant material 54 may be formed on the light-altering material 52 to fill one or more remaining portions of the recess 16_{R}. The encapsulant material 54 may embody a light-transmissive and/or light-transparent layer and may include materials such as silicone. In certain embodiments, a wavelength conversion element 56 may be arranged on the LED chip 20. The wavelength conversion element 56 may comprise a lumiphoric material in various form factors, such as a layer of lumiphoric material supported by a transparent support substrate (e.g., glass or sapphire), a phosphor-in-glass structure, or a ceramic phosphor plate. As illustrated, the light-altering material 52 may be arranged up to a height of the wavelength conversion element 56, thereby reflecting and/or refracting laterally propagating light from the LED chip 20 and/or the wavelength conversion element 56. In certain embodiments, the LED package 50 may further include a lens 58 extending up from the housing 16. The lens 58 may have various shapes for tailoring targeted emission patterns for the LED package 50. By way of example, the lens 58 in FIG. 8 forms a curved or dome shape above the housing 16. The lens 58 may comprise the same material as the encapsulant material 54 and may be a continuous extension thereof. In other embodiments, the lens 58 is a different material that resides on a top surface of the encapsulant material 54. In still further embodiments, the lens 58 may be omitted such that at top surface of the encapsulant material 54 forms a generally planar surface or a slight meniscus at a top of the housing 16.

FIG. 9 is a cross-sectional view of an LED package 60 similar to the LED package 50 of FIG. 8 with an alternative shape for the lens 58. As illustrated, the shape of the lens 58 may taper outward in a direction away from the LED chip 20. Moreover, the lens 58 may be formed with a generally planar surface in a position spaced away from a top surface of the housing 16.

Various combinations of the previously described embodiments are contemplated. For example, the discontinuous structure for the metal pads 18-1, 18-2 of FIGS. 5A to 7 may be implemented with any of the other embodiments described with respect to FIGS. 1A to 4B and/or FIGS. 8 and 9. Moreover, the shape of the lens 58 and/or the light-altering material 52 as described with respect to FIGS. 8 and 9 are two of various possible shapes that may be implemented in combination with any of the embodiments of FIGS. 1A to 7. Specifically, the lens 58 may be implemented in any of the previously described embodiments with respect to FIGS. 1A to 7.

Aspects of the present disclosure as described above for FIGS. 1A to 9 may be applicable to LED packages with single or multiple chips positioned within the recess of the housing 16. For multiple chip embodiments, each LED chip 20 may be separately mounted to the same pair of leads 14-1, 14-2, or each LED chip may be mounted to different pairs of leads of lead frame structures to provide individual addressability to each LED chip of a same LED package. Embodiments of the present disclosure may be well suited for various LED device applications, such as lighting fixtures or LED displays.

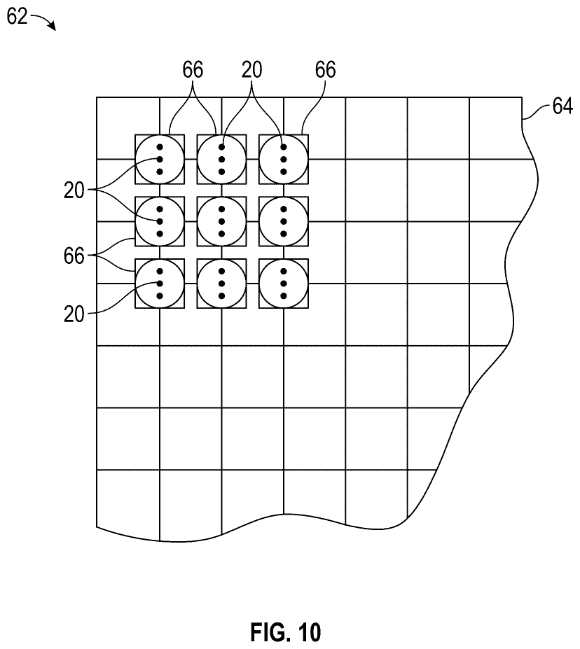

FIG. 10 is a schematic diagram of a portion of an LED device 62, such as a display screen, for example, an indoor and/or outdoor screen comprising, in general terms, a display panel including a driver printed circuit board (PCB) 64 carrying a large number of surface-mount devices (SMDs) 66 arranged in rows and columns, each SMD 66 defining a pixel. The SMDs 66 may comprise LED chip bonding structures 32 from any of the embodiments described above with respect to FIGS. 1A to 9. Additionally, each SMD 66 may represent a multiple chip embodiment of different colors, such as red-green-blue, for forming an LED pixel. The SMDs 66 are electrically connected to traces or pads on the PCB 64 to respond to appropriate electrical signal processing and driver circuitry (not shown). While FIG. 10 depicts the LED chips 20 in a linear arrangement within each LED package for the SMDs 66, in other embodiments, the LED chips 20 may be arranged in different configurations. During formation of the LED device 62, the LED chip bonding structures described above form non-reflowable metal structures that remain in solidus states at temperatures needed to bond the SMDS 66 to the PCB 64. In this regard, mechanical and electrical integrity of die attach for the LED chips 20 within each SMD 66 may be improved.

As described above, it is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a housing forming a recess with a recess floor;
a lead frame within the housing;
a metal pad in the recess, the metal pad formed on only a portion of the lead frame;
an LED chip on the metal pad; and
a bonding structure between the LED chip and the metal pad, the bonding structure comprising a non-reflowable metal structure configured to remain in a solidus state at temperatures up to at least 280 degrees Celsius (° C.).

2. The LED package of claim 1, wherein the non-reflowable metal structure is configured to remain in a solidus state at temperatures up to at least 380° C.

3. The LED package of claim 1, wherein the non-reflowable metal structure is configured to remain in a solidus state at temperatures in a range from 245° C. to 380° C.

4. The LED package of claim 1, wherein the metal pad comprises nickel.

5. The LED package of claim 4, wherein the bonding structure comprises an alloy layer comprising nickel and a metal of a solder material.

6. The LED package of claim 5, wherein the metal of the solder material comprises tin and the alloy layer comprises nickel-tin.

7. The LED package of claim 5, wherein the metal of the solder material comprises one or more of gold, antimony-tin, tin-silver-copper, and tin-lead.

8. The LED package of claim 5, wherein the alloy layer is a first alloy layer at a first interface with the metal pad, and the bonding structure further comprises a second alloy layer at a second interface with a contact pad of the LED chip, and the second alloy layer comprises the metal of the solder material.

9. The LED package of claim 5, wherein the alloy layer is continuous from a first interface with the metal pad to a second interface with a contact pad of the LED chip.

10. The LED package of claim 1, wherein a thickness of the metal pad above the recess floor is in a range from 5 (microns) μm to 25 μm.

11. The LED package of claim 1, wherein:
a portion of the lead frame extends above the recess floor; and
the metal pad covers a top surface of the lead frame and one or more perimeter sidewalls of the lead frame above the recess floor.

12. The LED package of claim 1, wherein:
a top surface of the lead frame is below the recess floor; and
the metal pad covers the top surface of the lead frame.

13. The LED package of claim 1, wherein the metal pad is discontinuous between a contact pad of the LED chip and a lead of the lead frame.

14. The LED package of claim 13, wherein the metal pad forms an array pattern on the lead of the lead frame.

15. The LED package of claim 1, further comprising a light-altering material on the recess floor and covering perimeter sidewalls of the LED chip.

16. The LED package of claim 1, further comprising at least one metal pillar, wherein peripheral edges of the at least one metal pillar are laterally surround by the metal pad.

17. A lead frame structure for a light-emitting diode (LED) package, the lead frame structure comprising:
a housing forming a recess with a recess floor;
a lead frame comprising a first lead within the housing, a portion of the first lead being positioned along the recess floor; and
a first metal pad on the portion of the first lead at the recess floor, the first metal pad comprising nickel.

18. The lead frame structure of claim 17, wherein a thickness of the first metal pad above the first lead is in a range from 5 (microns) μm to 25 μm.

19. The lead frame structure of claim 17, wherein:
a portion of the first lead extends above the recess floor; and
the first metal pad covers a top surface of the first lead and one or more perimeter sidewalls of the first lead above the recess floor.

20. The lead frame structure of claim 17, wherein:
a top surface of the first lead is below the recess floor; and
the first metal pad covers the top surface of the first lead.

21. The lead frame structure of claim 17, wherein the first metal pad is discontinuous on the first lead.

22. The lead frame structure of claim 17, wherein the lead frame comprises a second lead within the housing and a portion of the second lead is positioned along the recess floor, wherein the first lead and the second lead collectively form a die attach area.

23. The lead frame structure of claim 22, further comprising a second metal pad on the portion of the second lead at the recess floor, the second metal pad comprising nickel.

24. A lighting device comprising:
a board; and
a light-emitting diode (LED) package mounted on the board, the LED package comprising:
a housing forming a recess with a recess floor;
a lead frame within the housing;
a metal pad in the recess, the metal pad formed on only a portion of the lead frame;
an LED chip on the metal pad; and
a bonding structure between the LED chip and the metal pad, the bonding structure comprising a non-reflowable metal structure configured to remain in a solidus state at temperatures up to at least 280 degrees Celsius (° C.).

25. The lighting device of claim 24, wherein the non-reflowable metal structure is configured to remain in a solidus state at temperatures in a range from 245° C. to 380° C.

26. The lighting device of claim 24, wherein the metal pad comprises nickel.
